(19) United States
(12) Patent Application Publication
(10) Pub. No.: US 2012/0307850 A1
(43) Pub. Date: Dec. 6, 2012

(54) PULSED LIGHT GENERATION METHOD

(75) Inventors: Motoki KAKUI, Yokohama-shi (JP); Shinobu TAMAOKI, Yokohama-shi (JP)

(73) Assignee: SUMITOMO ELECTRIC INDUSTRIES, LTD., Osaka-shi (JP)

(21) Appl. No.: 13/485,585

(22) Filed: May 31, 2012

Related U.S. Application Data
(60) Provisional application No. 61/506,922, filed on Jul. 12, 2011.

(30) Foreign Application Priority Data
Jun. 3, 2011 (JP) 2011-125584

(51) Int. Cl. H01S 5/062

(52) U.S. Cl. 372/25

(57) ABSTRACT

The present invention relates to a method of enabling generation of pulsed lights each having a narrow pulse width and high effective pulse energys. A pulse light source has a MOPA structure, and comprises a single semiconductor laser, a bandpass filter and an optical fiber amplifier. The single semiconductor laser outputs two or more pulsed lights separated by a predetermined interval, for each period given according to a predetermined repetition frequency. The bandpass filter attenuates one of the shorter wavelength side and the longer wavelength side, in the wavelength band of input pulsed lights.

### CROSS-REFERENCE TO RELATED APPLICATION

This application is based upon and claims the benefit of priorities from U.S. Provisional Application No. 61/506,922, filed on Jul. 12, 2011 and Japanese Patent Application No. 2011-125584, filed on Jun. 3, 2011, the entire contents of which are incorporated herein by reference.

### BACKGROUND OF THE INVENTION

1. Field of the Invention

The present invention relates to a pulsed light generation method.

2. Related Background Art

A pulse light source is used for industrial purposes represented by laser processing, or the like. Generally, in laser processing of a fine target to be processed, to control constantly the pulse width of pulsed laser light is important for managing the processing quality including a thermal influence on the surroundings. Light outputted from an optical fiber laser light source, including an amplifying optical fiber that has a core doped with a rare earth element as an amplifying medium, has diffraction-limited beam quality, so that it is easily condensed into a narrow region, and such light is preferably used for fine processing. Japanese Patent Application Laid-Open No. 2009-152560 (Patent Document 1) discloses an invention of compressing a width of pulsed light in a pulse light source having a MOPA structure that amplifies pulsed light outputted from a seed light source by an optical fiber amplifier.

Japanese Patent Application Laid-Open No. 2010-171260 (Patent Document 2) discloses an invention of repeatedly outputting one pulsed light with a plurality of peaks corresponding to a plurality of modulation voltage pulse components, by changing a modulation voltage level to be applied to a seed light source. International Publication No. 2005-018064 (Patent Document 3) discloses an invention of repeatedly generating one pulse driving current with a plurality of peaks, and generating, based on the driving current, one pulsed light with a plurality of peaks from a seed light source, as shown in for example FIG. 10A. International Publication No. 2003-052890 (Patent Document 4) discloses an invention of preparing a plurality of pulse light sources each outputting a plurality of pulsed lights according to the same repetition frequency, and outputting a pulse group including one set of the plurality of pulsed lights, by multiplexing the pulsed light groups, each including a plurality of pulsed lights outputted from one pulse light source, outputted from the plurality of different pulse light sources at different times.

### SUMMARY OF THE INVENTION

The present inventors have examined the above prior art, and as a result, have discovered the following problems. That is, generally, in an optical fiber laser light source, when performing a shortening of output pulsed light, an increase in pulse peak is limited by restrictions of a nonlinear effect such as stimulated Raman scattering (SRS) and small-signal gain of a gain medium in an optical fiber. In order to avoid appearance of a nonlinear effect, the core diameter of the optical fiber may be increased, however, in this case, there is a risk of deteriorating the beam quality. On the other hand, it is preferable to compress a pulse width, so that pulse energy that determines the efficiency of laser processing and optical damage is limited.

The present invention has been developed to eliminate the problems described above. It is an object of the present invention to provide a method of enabling generation of pulsed lights each having a narrow pulse width and high effective pulse energy

A pulsed light generation method according to the present invention generates pulsed lights each having a narrow pulse width and high effective pulse energy, by using a laser light source having a specific structure. The laser light source comprises a single semiconductor laser, an optical filter, and an optical fiber amplifier. The single semiconductor laser is directly modulated at a predetermined repetition frequency and outputs pulsed light. The optical filter attenuates one of the shorter wavelength side and the longer wavelength side of a peak wavelength of the pulsed light outputted from the semiconductor laser, in a wavelength band of the pulsed light. The optical fiber amplifier amplifies the pulsed light outputted from the optical filter. In particular, a first aspect of the present invention outputs two or more pulsed lights from the single semiconductor laser for each predetermined period given according to a predetermined repetition frequency, the two or more pulsed lights being separated from each other by a predetermined interval. As a second aspect applicable to the first aspect, the period given according to the predetermined repetition frequency is preferably 100 ns or less.

The pulsed light generation method according to the present invention makes the single semiconductor laser output the plurality of pulsed lights separated from each other by a predetermined pulse width, for each period given according to the predetermined repetition frequency. In this manner, by outputting the plurality of pulsed lights within a primary pulse generation period, the present invention is superior in a point that resistance characteristics to stimulated Raman scattering (SRS) and stimulated Brillouin scattering (SBS) can be improved, and a point that a heat reserve in a laser processing can be reduced. On the other hand, Patent Documents 2 and 3 are different from the present invention in that the inventions of these documents output only one pulse for each period given according to a repetition frequency. The invention of Patent Document 4 obtains a plurality of pulsed lights in one period given according to a repetition frequency, by multiplexing the plurality of pulsed lights from the plurality of different pulse light sources at different times. However, Patent Document 4 is different from the present invention in that each pulse light source of this document outputs only one pulse in one period given according to a repetition frequency.

As a third aspect applicable to at least any one of the first and second aspects, in the pulsed light generation method according to the present invention, the full width at half maximum of each waveform of the two or more amplified pulsed lights outputted from the optical fiber amplifier for each period given according to the predetermined repetition frequency is preferably less than 300 ps. As a fourth aspect applicable to at least any one of the first to third aspects, the full width at half maximum of the waveform of a first amplified pulsed light, out of the two or more amplified pulsed lights outputted from the optical fiber amplifier for each period given according to the predetermined repetition frequency, is preferably wider than the full width at half maximum of each waveform of other amplified pulsed lights. As a fifth aspect applicable to at least any one of the first to fourth aspects, in an amplifying optical fiber at the final stage of the optical fiber amplifier, the propagation mode of at least a part of wavelength components of input pulsed lights is preferably a single transverse mode. Further, as a sixth aspect applicable to at least any one of the first to fifth aspect, the two or more pulsed lights separated from each other are generated by modulating the single semiconductor laser with a driving current or a modulation voltage level.

### BRIEF DESCRIPTION OF THE DRAWINGS

FIG. 1 is a view showing a configuration of an embodiment of a pulse light source (laser light source) for carrying out a pulsed light generation method according to the present invention;

FIGS. 2A to 2C are views each showing an example of a waveform of output light from the pulse light source the pulse light source of FIG. 1;

FIG. 3 is a view showing an example of a waveform of output light from a pulse light source, as a comparative example;

FIG. 4 is a view showing waveforms of output light from a pulse light source, as Sample 1 of the comparative example;

FIG. 5 is a view showing waveforms of output light from a pulse light source, as Sample 2 of the comparative example;

FIG. 6 is a view showing waveforms of output light from a pulse light source, as Sample 3 of the comparative example;

FIG. 7 is a view showing waveforms of output light from a pulse light source, as Sample 4 of the comparative example;

FIGS. 8A and 8B are views each showing waveforms of output light from a pulse light source, as Sample 1 of the present embodiment;

FIGS. 9A and 9B are views each showing waveforms of output light from a pulse light source, as Sample 2 of the present embodiment;

FIGS. 10A and 10B are views each showing waveforms of output light from a pulse light source, as Sample 3 of the present embodiment;

FIGS. 11A and 11B are views each showing waveforms of output light from a pulse light source, as Sample 4 of the present embodiment;

FIGS. 12A and 12B are views each showing waveforms of output light from a pulse light source, as Sample 5 of the present embodiment;

FIG. 13 is a graph showing relationships between repetition frequencies and full widths at half maximum (FWHM) of output pulsed lights in the samples of the comparative example and the samples of the present embodiment; and

FIG. 14 is a graph showing relationships between repetition frequencies and pulse energies of output pulsed lights in the samples of the comparative example and the samples of the present embodiment.

### DESCRIPTION OF THE PREFERRED EMBODIMENTS

In the following, a best mode for carrying out the present invention is described in detail with reference to the accompanying drawings. In the description of the drawing, elements identical to each other are denoted with the same reference numerals, and overlapping description is omitted.

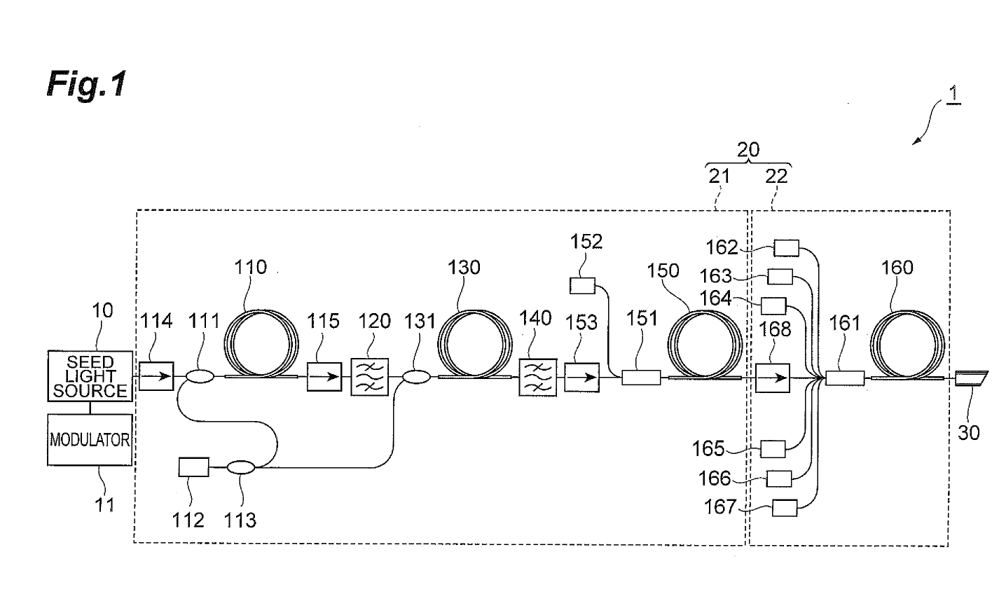

FIG. 1 is a view showing a configuration of an embodiment of a pulse light source (laser light source) for carrying out a pulsed light generation method according to the present invention. In FIG. 1, the pulse light source 1 has a MOPA (Master Oscillator Power Amplifier) structure, and comprises a seed light source 10 directly modulated by a modulator 11 and an optical fiber amplifier 20. The seed light source 10 includes a 1060 nm-band Fabry-Perot semiconductor laser that is directly pulse-modulated in a drive current range of 0 to 220 mA so as to realize a high repetition frequency of from 100 kHz to upper limit of 1 MHz or 10 MHz and a constant pulse width without depending on the repetition frequency. The seed light source 10 outputs two or more pulsed lights separated from each other from the semiconductor laser for each period given according to the predetermined repetition frequency. The seed light source 10 is directly modulated according to modulation current or modulation voltage level. The separated two or more pulsed lights may be outputted within the time of 100 ns that is included in one period given according to the predetermined repetition frequency, or the period given according to the predetermined repetition frequency may be 100 ns or less.

The optical fiber amplifier 20 includes a preamplifier 21 and a booster amplifier 22. The preamplifier 21 includes a YbDF 110, a bandpass filter 120, a YbDF 130, a bandpass filter 140, and a YbDF 150, and the like. The booster amplifier 22 includes a YbDF 160, and the like. The preamplifier 21 and the booster amplifier 22 are optical fiber amplifiers, respectively, amplify pulsed lights repetitively outputted from the seed light source 10 and output the pulsed lights from an end cap 30. The pulse light source 1 outputs pulsed lights with wavelengths around 1060 nm preferable for laser processing.

The YbDFs 110, 130, 150, and 160 are optical amplifying media that amplify pulsed lights with wavelengths around 1060 nm outputted from the seed light source 10 and include the optical fibers composed of silica glass whose cores are doped with a Yb element as an active substance. The YbDFs 110, 130, 150, and 160 are advantageous in terms of power conversion efficiency because the wavelengths of pumping light and light to be amplified are near, and advantageous because they have a high gain at a wavelength around 1060 nm. These YbDFs 110, 130, 150 and 160 constitute a four-stage optical fiber amplifier.

To the YbDF 110 at the first stage, pumping light that is outputted from a pumping light source 112 and passed through a optical coupler 113 and an optical coupler 111 is supplied in the forward direction. Additionally, into the YbDF 110, pulsed lights from the seed light source 10 that passed through an optical isolator 114 and the optical coupler 111 are also inputted. The input pulsed lights are amplified in the YbDF 110, and then outputted through an optical isolator 115.

Into the bandpass filter 120, pulsed lights that passed through the optical isolator 115 (pulsed lights amplified by the YbDF 110 at the first stage) are inputted. The bandpass filter 120 attenuates one of the shorter wavelength side and the longer wavelength side, in the wavelength band of the input pulsed light.

To the YbDF 130 at the second stage, pumping light from the pumping light source 112 that passed through the optical coupler 113 and an optical coupler 131 is supplied in the forward direction. Then, the YbDF 130 amplifies pulsed lights from the bandpass filter 120 that passed through the optical coupler 131.

The pulsed lights amplified by the YbDF 130 at the second stage are inputted into the bandpass filter 140. Then, the bandpass filter 140 attenuates one of the shorter wavelength side and the longer wavelength side, in the wavelength band of the input pulsed lights.

To the YbDF 150 at the third stage, pumping light from the pumping light source 152 that passed through an optical coupler 151 is supplied in the forward direction. Additionally, into the YbDF 150, pulsed lights from the bandpass filter 140 that passed through an optical isolator 153 and the optical coupler 151 are also inputted. Then, the YbDF 150 amplifies these input pulsed lights.

To the YbDF 160 at the fourth stage, pumping light from respective pumping light sources 162 to 167 that passed through an optical combiner 161 are supplied in the forward direction. Additionally, into the YbDF 160, pulsed lights that passed through an optical isolator 168 and the optical combiner 161 (pulsed lights amplified by the YbDF 150 at the third stage) are also inputted. The YbDF 160 amplifies the input pulsed lights, and then outputs the input pulsed lights to the outside of the laser light source 1 via the end cap 30. In the YbDF 160 at the fourth stage, at least a part of the wavelength components of the input pulsed lights is a single transverse mode.

A more preferable configuration example is as follows. Respective YbDFs 110, 120, and 130 are Al-codoped silica-based YbDFs having a single cladding structure and having an Al concentration of 5 wt %, a core diameter of 6 μm, a cladding diameter of 125 μm, 915 nm-band pumping light non-saturated absorption peak of 70 dB/m, and a 975 nm-band pumping light non-saturated absorption peak of 240 dB/m, and a length of 7 m. The YbDF 160 at the fourth stage is an Al-codoped silica-based YbDF having a double cladding structure and having an Al concentration of 1 wt %, a core diameter of 10 μm, a cladding diameter of 125 μm, and a 915 nm-band pumping light non-saturated absorption peak of 1.3 dB/m, and a length of 3.5 m.

All wavelengths of pumping light to be supplied to the YbDFs 110, 130, 150, and 160 are 0.975 μm band. The pumping light to be supplied to the YbDF 110 at the first stage has power of 200 mW, and the propagation mode thereof is a single transverse mode. The pumping light to be supplied to the YbDF 130 at the second stage has power of 200 mW, and the propagation mode thereof is a single transverse mode. The pumping light to be supplied to the YbDF 150 at the third stage has power of 400 mW, and the propagation mode thereof is a single transverse mode. The pumping light to be supplied to the YbDF 160 at the fourth stage has power of 21 to 30 W, and the propagation mode thereof is a multiple mode. Hereinafter, the case where power of pumping light to be supplied to the YbDF 160 at the fourth stage is 30 W is defined as 100%, and as a relative ratio to this, the pumping light power is expressed.

By intentionally shifting the respective center wavelengths of the bandpass filters 120 and 140 to the shorter wavelength side or the longer wavelength side from a maximum intensity wavelength of an output light spectrum of the seed light source 10, only chirping components can be extracted from seed light outputted from the seed light source 10. Then, by amplifying the extracted light, pulsed lights with short pulse widths can be generated. The bandpass filters 120 and 140, respectively, can remove ASE light. The full widths at half maximum of transmission spectra of the respective bandpass filters 120 and 140 are kept at 1 ns or lower, for example.

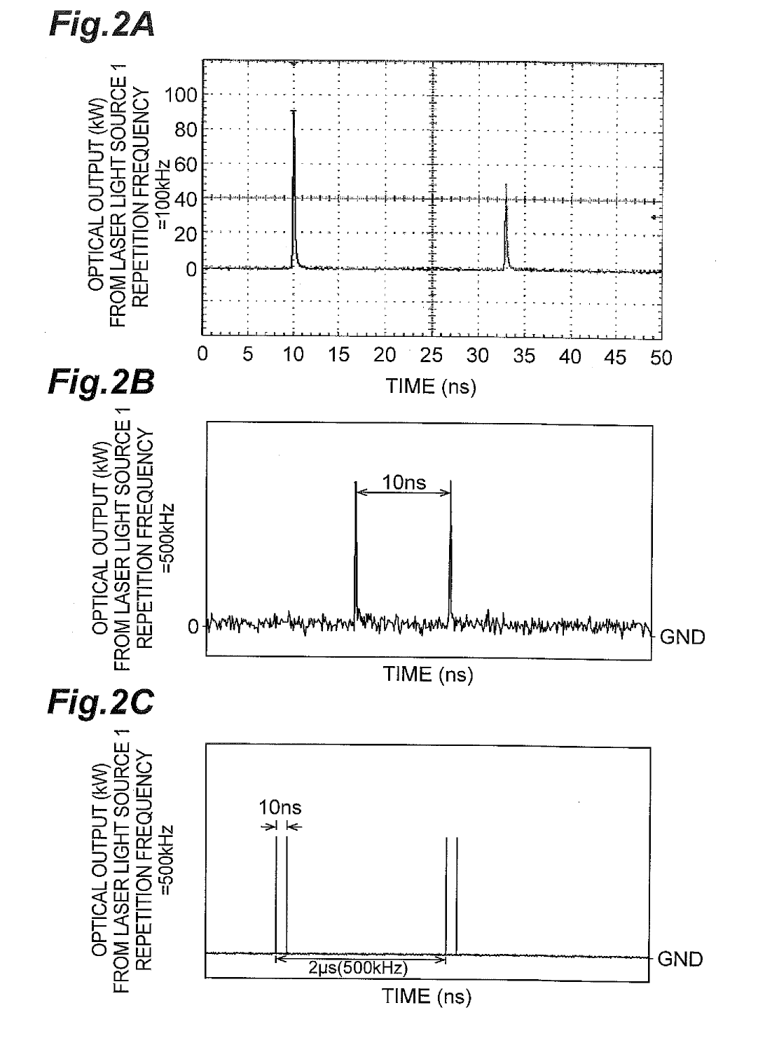

FIG. 2A is a view showing an example of a waveform of output light from the pulse light source 1, as an example of the present embodiment. In the example shown in FIG. 2A, the pulse light source is operated so that pulsed lights separated from each other are outputted from the seed light source 10 for each period given according to a repetition frequency 100 kHz within the time of 100 ns. Namely, from the seed light source 10, first pulsed light was outputted, and 20 ns later, second pulsed light was outputted. This pulse interval of 20 ns is set to be shorter than the pulsed light output interval of 100 ns of a Q-switch type laser light source used often for laser processing. FIG. 2B is a view showing an another example of a waveform of output light from the pulse light source 1, as an example of the present embodiment. In the example of FIG. 2B, the pulse light source 1 is operated so that two pulsed lights are outputted from the seed light source 10 for each period given according to a predetermined frequency 500 kHz. Namely, from the seed light source 10, first pulsed light was outputted, and 10 ns later, second pulsed light was outputted. In this case, as shown in FIG. 2C, two pulsed lights that are separated by 10 ns are outputted within a period of 2 μm.

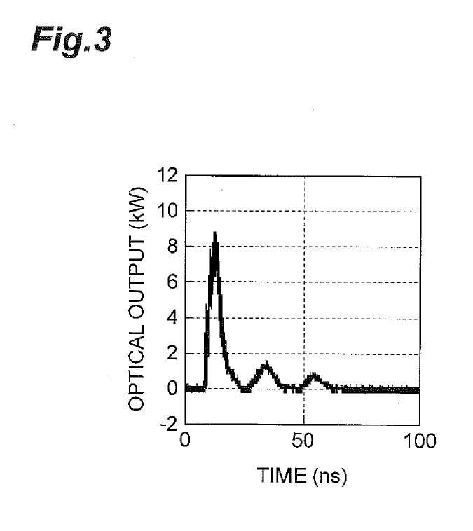

FIG. 3 is a view showing an example of a waveform of output light of a pulse light source, as a comparative example. In the comparative example, the pulse light source has a configuration obtained by removing the bandpass filters 120 and 140 from the configuration shown in FIG. 1. Here, in the example shown in FIG. 3, from the seed light source, first pulsed light was outputted for each period given according to a repetition frequency of 300 kHz, and 20 ns later, second pulsed light was outputted. Another 20 ns later, third pulsed light was outputted.

As comparing the output light waveforms shown in FIGS. 2A, 2B and 3 with each other, the following is found. In the comparative example (FIG. 3), even the sum of energies of the second pulsed light and the third pulsed light outputted from the optical fiber amplifier is less than ½ of pulse energy of the first pulsed light. The reason for this is that according to transient response in the optical fiber amplifier, by amplifying the first pulsed light outputted from the seed light source by the optical fiber amplifier, energy accumulated in the optical fiber amplifier is released all at once, so that when the second pulsed light outputted from the seed light source is inputted into the optical fiber amplifier, the second pulsed light outputted from the optical fiber amplifier does not grow. As compared with the case where only the first pulsed light is irradiated, the sum of pulse energies hardly increases in the comparative example. Therefore, the second pulsed light and the third pulsed light outputted from the optical fiber amplifier hardly contribute to laser processing.

On the other hand, in the present embodiment, by intentionally shifting the respective center wavelengths of the bandpass filters 120 and 140 to the shorter wavelength side or the longer wavelength side from the maximum intensity wavelength of output light spectrum of the seed light source 10, only chirping components are extracted from the seed light outputted from the seed light source 10. Therefore, when the first pulsed light outputted from the seed light source 10 is amplified in the optical fiber amplifier 20, a part of energy accumulated in the optical fiber amplifier 20 is released, and even when the second pulsed light outputted from the seed light source 10 is inputted into the optical fiber amplifier 20, sufficient energy is accumulated in the optical fiber amplifier 20. Therefore, the second pulsed light outputted from the optical fiber amplifier 20 can sufficiently have high peak power.

Next, examples of output light waveforms of pulse light sources as a plurality of samples of the comparative example and a plurality of samples of the present embodiment, respectively, are shown, and compared in detail with each other. In the samples of the comparative example, only one pulsed light was outputted from the seed light source for each period given according to a predetermined repetition frequency. In the samples of the present embodiment, two pulsed lights were outputted at an interval of 20 ns from the seed light source for each period given according to a predetermined repetition frequency. In all of the samples of the comparative example and the samples of the present embodiment, the temperature of the seed light source 10 was set to 37° C.,

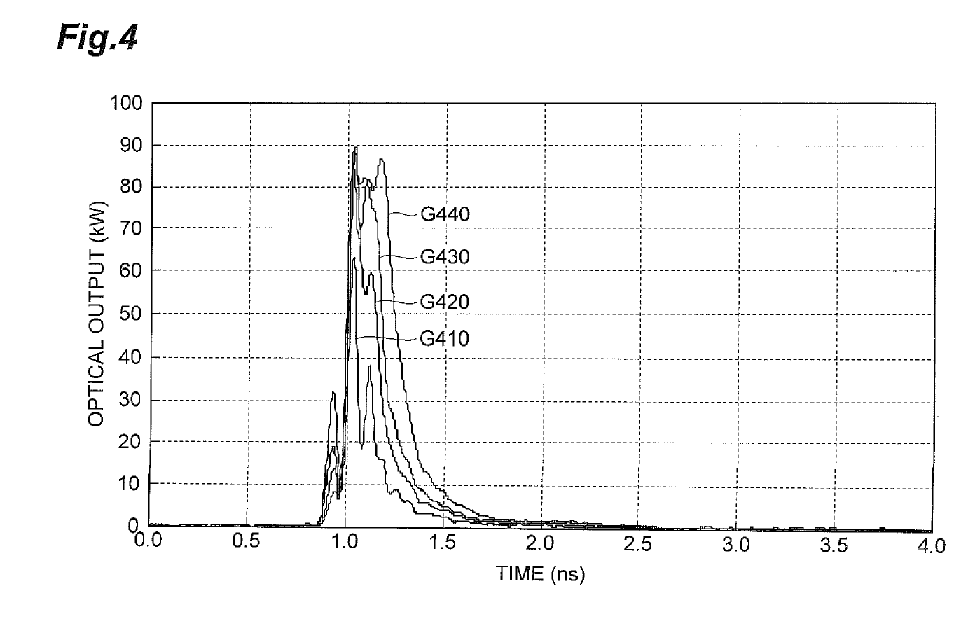

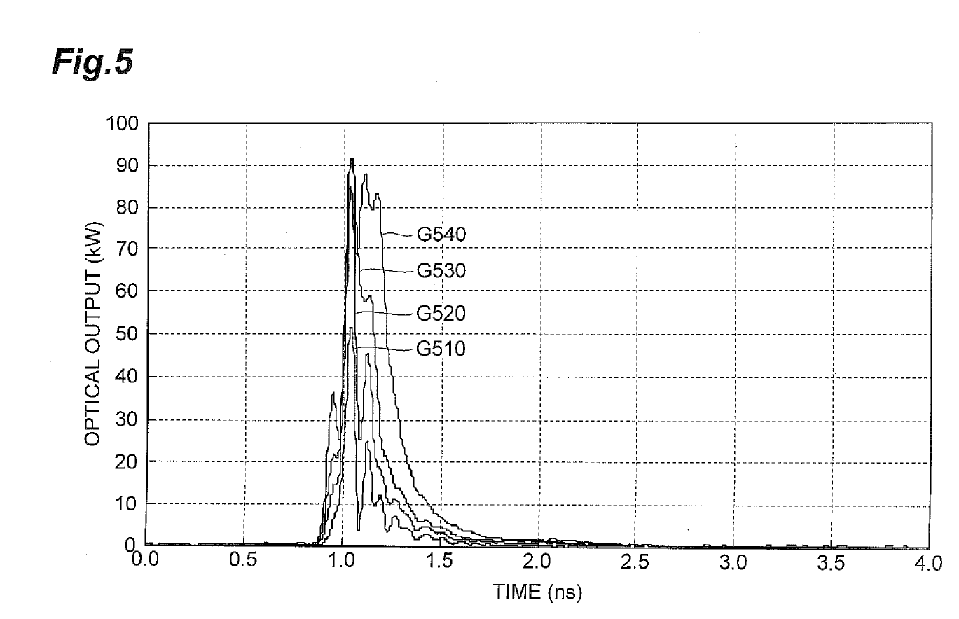

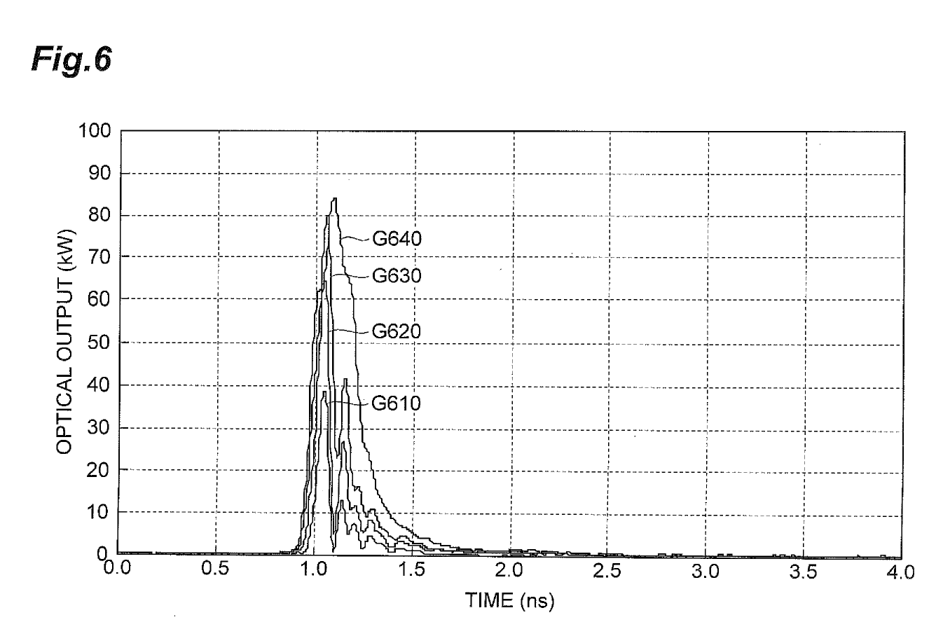

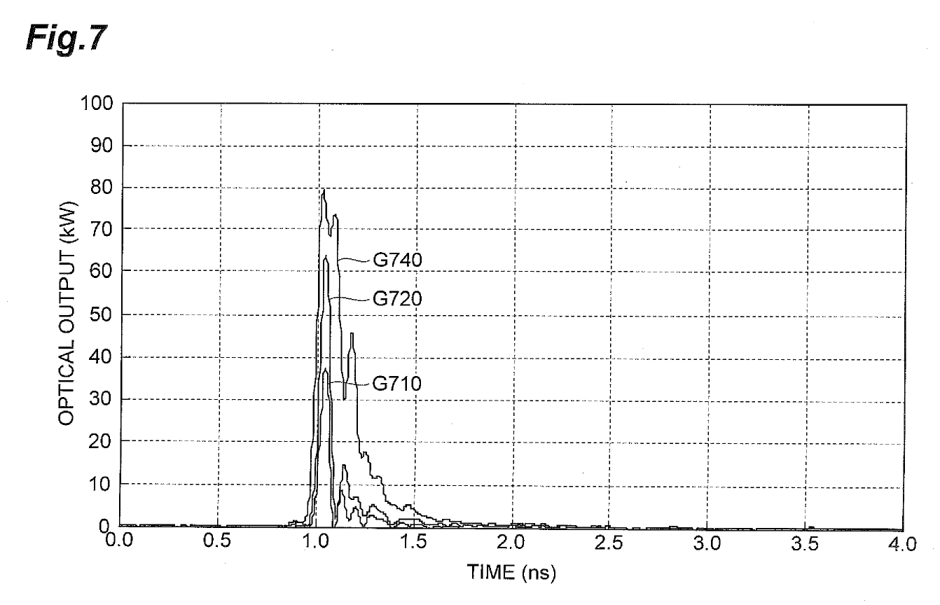

FIGS. 4 to 7 are views showing output light waveforms of the pulse light sources, as Samples 1 to 4 of the comparative example. FIGS. 4 to 7 show output light waveforms in the cases where the pumping light power of the YbDF 160 at the fourth stage was set to 30%, 50%, 70%, and 100%, respectively. FIG. 4 shows output light waveforms when the repetition frequency was set to 100 kHz, and in detail, shows four graphs in the cases where the pumping light power of the YbDF 160 at the fourth stage was set to 30% (graph G410), 50% (graph G420), 70% (graph G430), and 100% (graph G440). FIG. 5 shows output light waveforms when the repetition frequency was set to 300 kHz, and in detail, shows four graphs in the cases where the pumping light power of the YbDF 160 at the fourth stage was set to 30% (graph G510), 50% (graph G520), 70% (graph G530), and 100% (graph G540). FIG. 6 shows output light waveforms when the repetition frequency was set to 600 kHz, and in detail, shows four graphs in the cases where the pumping light power of the YbDF 160 at the fourth stage was set to 30% (graph G610), 50% (graph G620), 70% (graph G630), and 100% (graph G640). FIG. 7 shows output light waveforms when the repetition frequency was set to 1000 kHz, and in detail, shows three graphs in the cases where the pumping light power of the YbDF 160 at the fourth stage was set to 30% (graph G710), 50% (graph G720), and 100% (graph G740).

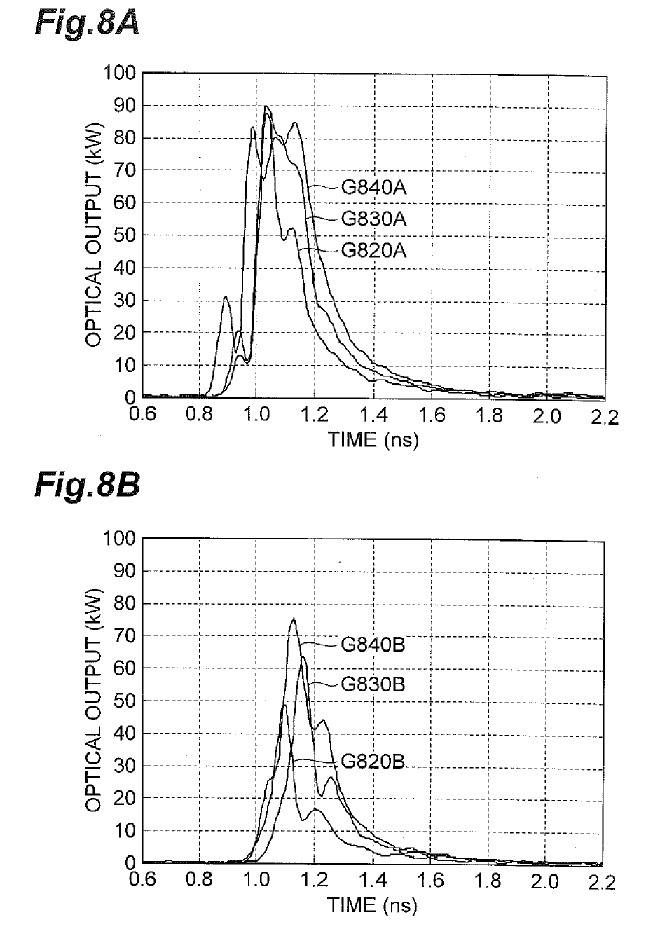

FIGS. 8A to 12B are views each showing output light wavefroms of the pulse light sources, as Samples 1 to 4 of the present embodiment. FIGS. 8A to 12B show output light waveforms in the cases where the pumping light power of the YbDF 160 at the fourth stage was set to 50%, 70%, and 100%, respectively.

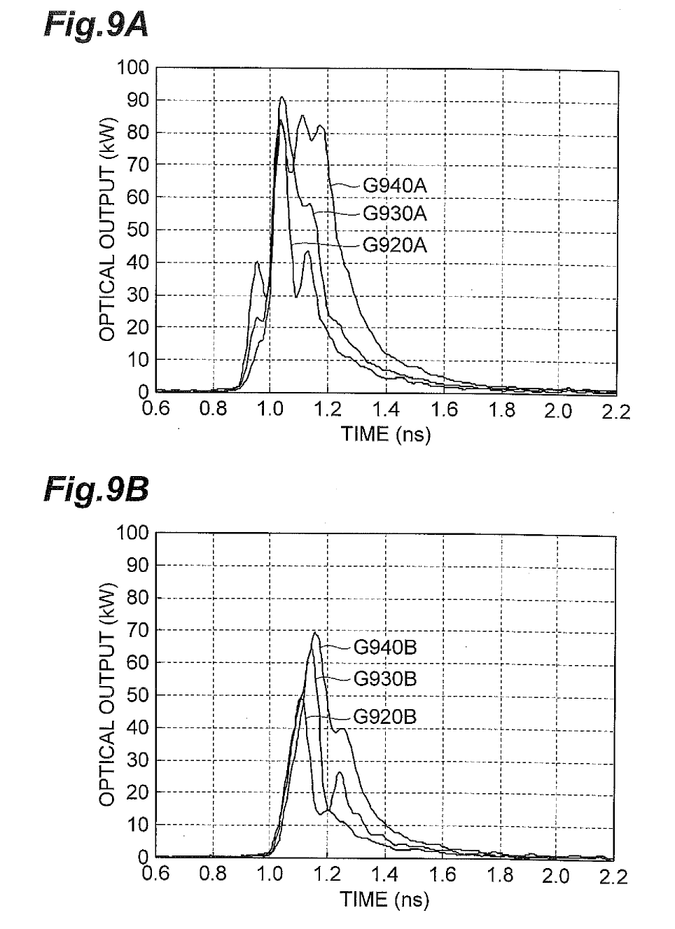

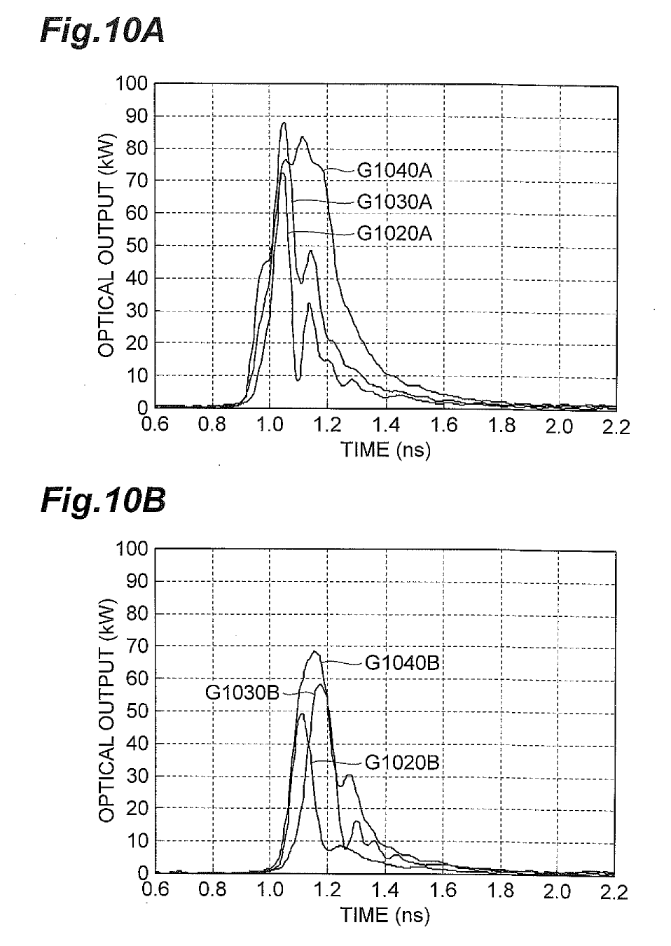

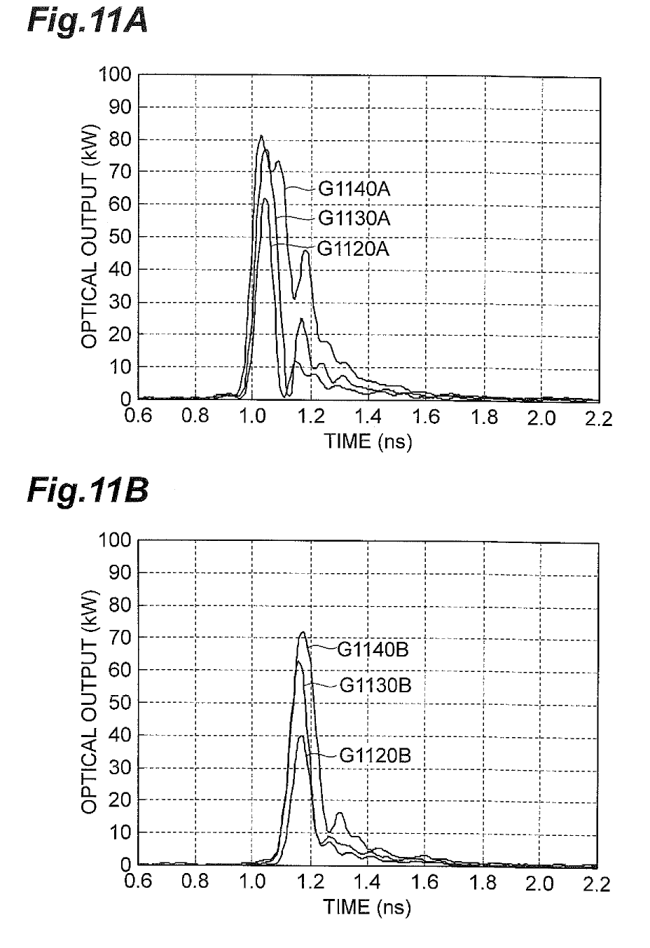

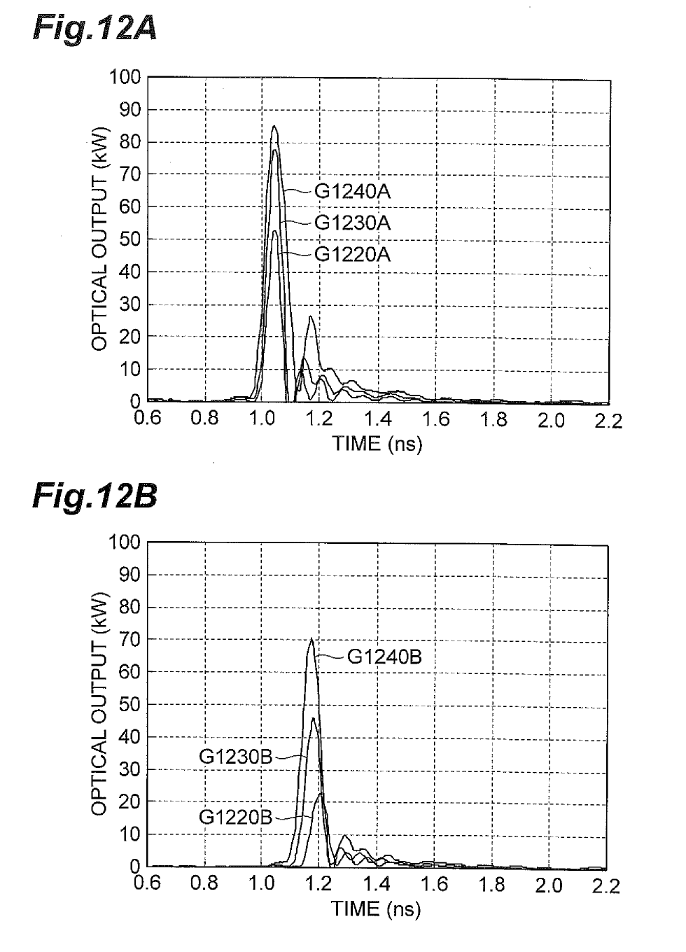

As waveforms of the first pulsed light outputted from the optical fiber amplifier 20, FIG. 8A shows output light waveforms when the repetition frequency was set to 100 kHz, and in detail, shows three graphs in the cases where the pumping light power of the YbDF 160 at the fourth stage was set to 50% (graph G820A), 70% (graph G830A), and 100% (graph G840A). FIG. 9A shows output light waveforms when the repetition frequency was set to 200 kHz, and in detail, shows three graphs in the cases where the pumping light power of the YbDF 160 at the fourth stage was set to 50% (graph G920A), 70% (graph G930A), and 100% (graph G940A). FIG. 10A shows output light waveforms when the repetition frequency was set to 300 kHz, and in detail, shows three graphs in the cases where the pumping light power of the YbDF 160 at the fourth stage was set to 50% (graph G1020A), 70% (graph G1030A), and 100% (graph G1040A). FIG. 11A shows output light waveforms when the repetition frequency was set to 600 kHz, and in detail, shows three graphs in the cases where the pumping light power of the YbDF 160 at the fourth stage was set to 50% (graph G1120A), 70% (graph G1130A), and 100% (graph G1140A). FIG. 12A shows output light waveforms when the repetition frequency was set to 1000 kHz, and in detail, shows three graphs in the cases where the pumping light power of the YbDF 160 at the fourth stage was set to 50% (graph G1220A), 70% (graph G1230A), and 100% (graph G1240A).

As waveforms of the second pulsed light outputted from the optical fiber amplifier 20, FIG. 8B shows output light waveforms when the repetition frequency was set to 100 kHz, and in detail, shows three graphs in the cases where the pumping light power of the YbDF 160 at the fourth stage was set to 50% (graph G820B), 70% (graph G830B), and 100% (graph G840B). FIG. 9B shows output light waveforms when the repetition frequency was set to 200 kHz, and in detail, shows three graphs in the cases where the pumping light power of the YbDF 160 at the fourth stage was set to 50% (graph G920B), 70% (graph G930B), and 100% (graph G940B). FIG. 10B shows output light waveforms when the repetition frequency was set to 300 kHz, and in detail, shows three graphs in the cases where the pumping light power of the YbDF 160 at the fourth stage was set to 50% (graph G1020B), 70% (graph G1030B), and 100% (graph G1040B). FIG. 11B shows output light waveforms when the repetition frequency was set to 600 kHz, and in detail, shows three graphs in the cases where the pumping light power of the YbDF 160 at the fourth stage was set to 50% (graph G1120B), 70% (graph G1130B), and 100% (graph G1140B). FIG. 12B shows output light waveforms when the repetition frequency was set to 1000 kHz, and in detail, shows three graphs in the cases where the pumping light power of the YbDF 160 at the fourth stage was set to 50% (graph G1220B), 70% (graph G1230B), and 100% (graph G1240B).

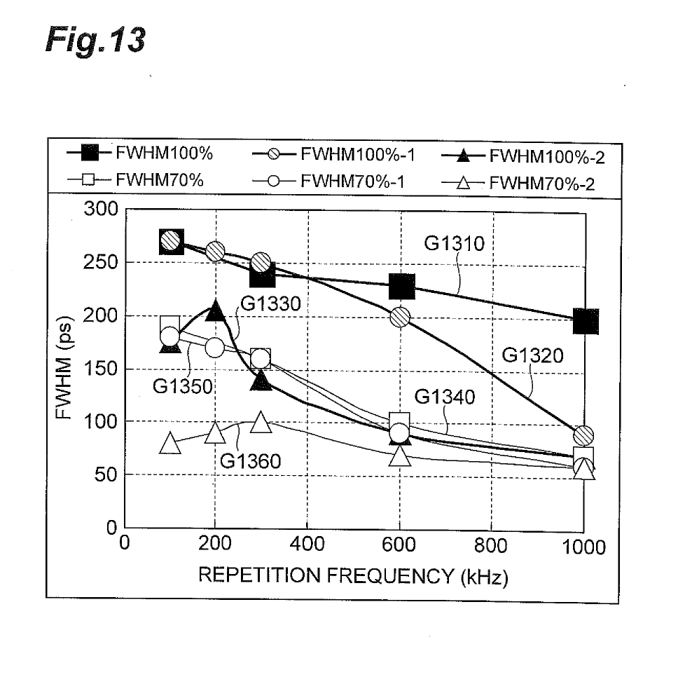

FIG. 13 is a graph showing relationships between repetition frequencies and full widths at half maximum (FWHM) of output pulsed lights in the samples of the comparative example and the samples of the present embodiment, respectively. In FIG. 13, the graph G1310 (indicated as “FWHM 100%”) shows the FWHM of output pulsed lights of the samples (pumping light power: 100%) of the comparative example, the graph G1320 (indicated as “FWHM 100%-1”) shows the FWHM of the first pulsed lights of the samples (pumping light power: 100%) of the present embodiment, and the graph G1330 (indicated as “FWHM 100%-2”) shows the FWHM of the second pulsed lights of the samples (pumping light power: 100%) of the present embodiment. The graph G1340 (indicated as “FWHM 70%”) shows the FWHM of output pulsed lights of the samples (pumping light power: 70%) of the comparative example, the graph G1350 (indicated as “FWHM 70%-1”) shows the FWHM of the first pulsed lights of the samples (pumping light power: 70%) of the present embodiment, and the graph G1360 (indicated as “FWHM 70%-2”) shows the FWHM of the second pulsed lights of the samples (pumping light power: 70%) of the present embodiment.

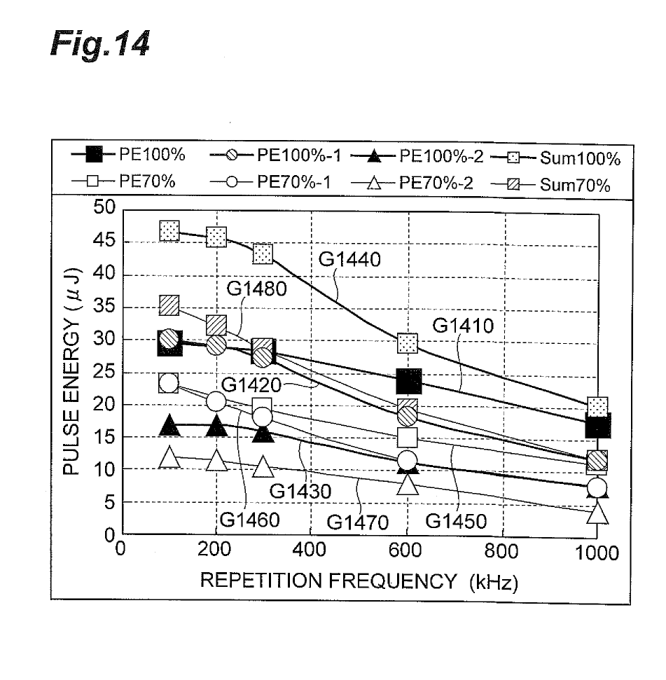

FIG. 14 is a graph showing relationships between repetition frequencies and pulse energies of output pulsed lights in the samples of the comparative example and the samples of the present embodiment, respectively. In FIG. 14, the graph G1410 (indicated as “PE 100%”) shows the pulse energies of output pulsed lights of the samples (pumping light power: 100%) of the comparative example, the graph G1420 (indicated as “PE 100%-1”) shows the pulse energies of the first pulsed lights of the samples (pumping light power: 100%) of the present embodiment, and the graph G1430 (indicated as “PE 100%-2”) shows the pulse energies of the second pulsed lights of the samples (pumping light power: 100%) of the present embodiment. The graph G1440 (indicated as “Sum 100%”) shows the sums of pulse energies of the first pulsed lights and the second pulsed lights, respectively, of the samples (pumping light power: 100%) of the present embodiment. The graph G1450 (indicated as “PE 70%”) shows the pulse energies of the output pulsed lights of the samples (pumping light power: 70%) of the comparative example, the graph G1460 (indicated as “PE 70%-1”) shows the pulse energies of the first pulsed lights of the samples (pumping light power: 70%) of the present embodiment, and the graph G1470 (indicated as “PE 70%-2”) shows the pulse energies of the second pulsed lights of the samples (pumping light power: 70%) of the present embodiment. The graph G1480 (indicated as “Sum 70%”) shows the sums of pulse energies of the first pulsed lights and the second pulsed lights, respectively, of the samples (pumping light power: 70%) of the present embodiment.

As can be seen from FIGS. 13 and 14, as compared with the samples of the comparative example, in the samples of the present embodiment, while the FWHM of the individual pulses are always narrow, the pulse energy increases to 1.5 times or more at any repetition frequency in the case where, for example, the pumping power of the YbDF 160 at the fourth stage is 100%. In the samples of the present embodiment, the FWHM of the two or more pulsed light waveforms outputted from the optical fiber amplifier 20 for each period are less than 300 ps. In addition, in the samples of the present embodiment, the FWHM of the waveform of the pulsed light outputted first, out of the two or more pulsed light outputted from the optical fiber amplifier 20 for each period, is wider than the FWHM of each waveform of other pulsed light.

In the present embodiment, the number of pulses in each period may not be two, and may be three or more. In the present embodiment, the wavelength to be amplified may not be 1.06 μm band, and may be 1.55 μm band as long as an optical amplifying medium doped with a rare earth element can operate in the wavelength band. The rare earth element may not be Yb, and may be Er or Nd.

In accordance with the present invention, pulsed lights with narrow pulse widths and high effective pulse energies can be generated.

What is claimed is:

1. A pulsed light generation method, comprising the steps of
preparing a laser light source comprising: a single semiconductor laser that is directly modulated at a predetermined repetition frequency and outputs pulsed light; an optical filter that attenuates one of the shorter wavelength side and the longer wavelength side with respect to a peak wavelength of the pulsed light outputted from the single semiconductor laser, in a wavelength band of the pulsed light; and an optical fiber amplifier that amplifies the pulsed light outputted from the optical filter; and
outputting two or more pulsed lights from the single semiconductor laser for each predetermined period given according to a predetermined repetition frequency, the two or more pulsed lights being separated by a predetermined pulse interval.

2. The pulsed light generation method according to claim 1, wherein the period given according to the predetermined repetition frequency is 100 ns or less.

3. The pulsed light generation method according to claim 2, wherein the full width at half maximum of the each waveform of the two or more amplified pulsed lights outputted from the optical fiber amplifier for each period given according to the predetermined repetition frequency is less than 300 ps.

4. The pulsed light generation method according to claim 2, wherein the full width at half maximum of the waveform of a first amplified pulsed light, out of the two or more amplified pulsed lights outputted from the optical fiber amplifier for each period given according to the predetermined repetition frequency, is wider than the full width at half maximum of each waveform of other amplified pulsed lights.

5. The pulsed light generation method according to claim 2, wherein an amplifying optical fiber at the final stage of the optical fiber amplifier guarantees a single transverse mode for at least a part of wavelength components of input pulsed lights.

6. The pulsed light generation method according to claim 1, wherein the two or more separated pulsed lights are generated by directly modulating the single semiconductor laser with modulation current or modulation voltage level.
